(19) United States
(12) Patent Application Publication
(10) Pub. No.: US 2023/0413487 A1
(43) Pub. Date: Dec. 21, 2023

(54) HEAT SINK AND ELECTRONIC DEVICE HAVING THE HEAT SINK

(71) Applicant: Fulian Precision Electronics (Tianjin) Co., LTD., Tianjin (CN)

(72) Inventor: XIANG-WU CHEN, Tianjin (CN)

(21) Appl. No.: 17/881,975

(22) Filed: Aug. 5, 2022

(30) Foreign Application Priority Data
Jun. 17, 2022 (CN) 202221522118.7

(51) Int. Cl. H05K 7/20; H05K 1/02; H01L 23/367

(52) U.S. Cl. CPC H05K 7/20409; H05K 1/0203; H01L 23/367; H05K 7/20336

(57) ABSTRACT

A heat sink includes a substrate, a heat pipe embedded in the substrate, a first fin group, and a plurality of heat conducting members. The substrate includes a first surface and a second surface facing away from the first surface. The first fin group is arranged on the first surface. A part of each of the plurality of heat conducting members is embedded in the substrate from the second surface and contacts the heat pipe, the other part of each of the plurality of heat conducting members is located outside of the substrate. An electronic device having the heat sink is also provided.

### FIELD

The subject matter herein generally relates to a heat sink and an electronic device having the heat sink.

### BACKGROUND

Most electronic devices include circuit board and a plurality of components on the circuit board. The plurality of components generates heat during operation, and the heat generated by the plurality of components needs to be dissipated in time to avoid affecting the normal operation of the components.

### BRIEF DESCRIPTION OF THE DRAWINGS

Implementations of the present disclosure will now be described, by way of embodiments, with reference to the attached figures.

FIG. 1 is a diagram of an embodiment of a heat sink according to the present disclosure viewed from a first perspective.

FIG. 2 is a diagram of an embodiment of a heat sink according to the present disclosure viewed from a second perspective.

FIG. 3 is an exploded, diagrammatic view of an embodiment of a heat sink according to the present disclosure.

FIG. 4 is a cross-sectional view of the heat sink taken along IV-IV line of FIG. 1.

FIG. 5 is a diagram of an embodiment of an electronic device according to the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

The term “comprising,” when utilized, means “including, but not necessarily limited to”; it specifically indicates open-ended inclusion or membership in the so-described combination, group, series, and the like.

An embodiment of a heat sink is provided for dissipating heat from multiple heat sources. The heat sink includes a substrate, a heat pipe, a first fin group, and a plurality of heat conducting members. The substrate includes a first surface and a second surface facing away from the first surface. The heat pipe is embedded in the substrate. The first fin group is arranged on the first surface. Each of the plurality of heat conducting members is embedded in the substrate and protrudes out of the substrate from the second surface. The heat pipe is in contact with each of the plurality of heat conducting members. In at least one embodiment, the heat sources are arranged along a direction, the heat pipe embedded in the substrate extends along the direction. Each of the plurality of heat conducting members corresponds to one of the heat sources, and is in contact with the corresponding heat source.

In the above heat sink, the plurality of heat conducting members are in contact with the heat sources and transmit the heat to the heat pipe, the heat pipe uniformly spreads the absorbed heat to the substrate and dissipates the heat though the first fin group.

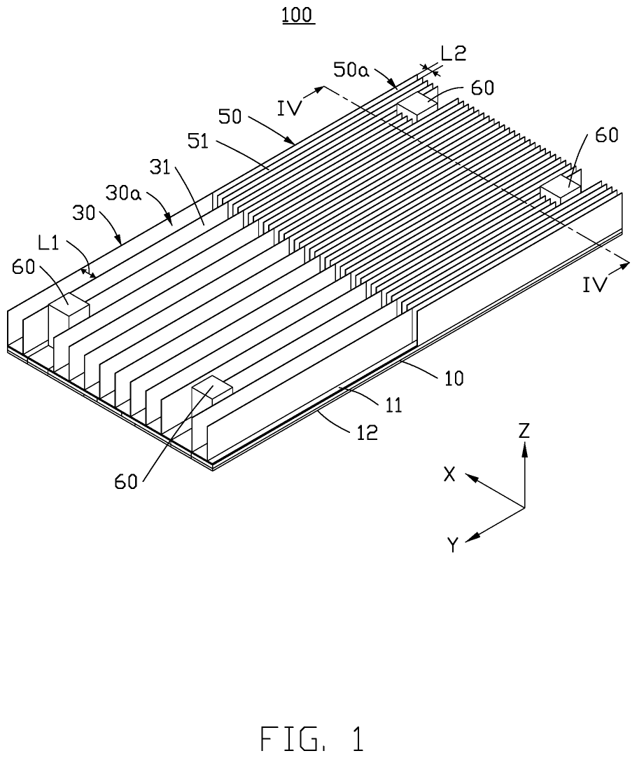

FIG. 1 illustrates an embodiment of a heat sink 100 for dissipating heat from multiple heat sources 90. In at least one embodiment, the heat sources 90 may be, but not limited to, components that dissipates heat on the circuit board.

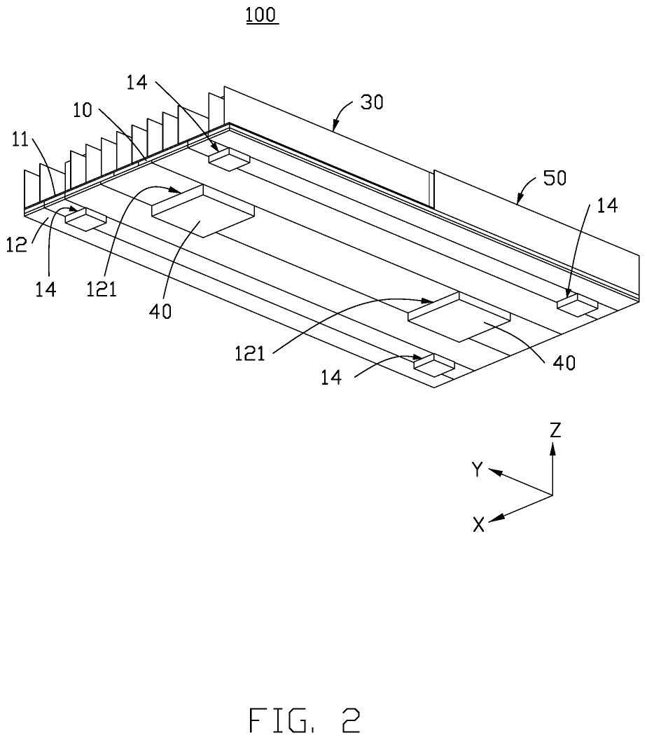

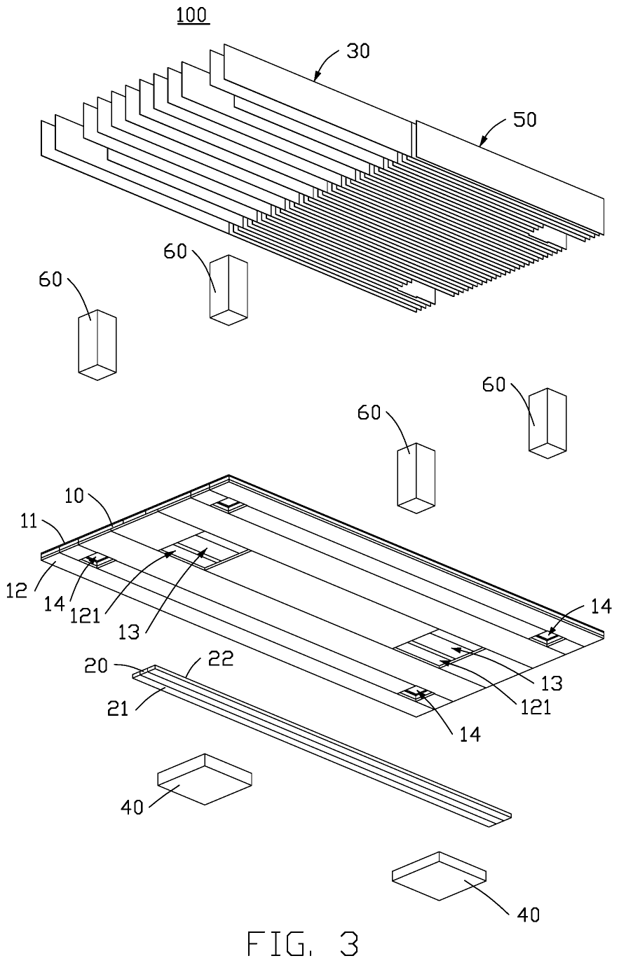

Referring to FIGS. 2 and 3, the heat sink 100 includes a substrate 10, a heat pipe a first fin group 30, and a plurality of heat conducting members 40. The substrate 10 includes a first surface 11 and a second surface 12 facing away from the first surface 11. The heat pipe 20 is embedded in the substrate 10. The first fin group 30 is arranged on the first surface 11. Each of the plurality of heat conducting members 40 is embedded in the substrate 10 and protrudes out of the substrate 10 from the second surface 12, that is, a part of each of the plurality of heat conducting members 40 is embedded in the substrate from the second surface 12, the other part of each of the plurality of heat conducting members 40 is located outside of the substrate 10. The heat pipe 20 is in contact with each of the plurality of heat conducting members 40. In at least one embodiment, the heat sources 90 are arranged along a direction, the heat pipe 20 embedded in the substrate 10 extends along the direction. Each of the plurality of heat conducting members 40 corresponds to one of the heat sources 90, and is in contact with the corresponding heat source 90.

In the above heat sink 100, the plurality of heat conducting members 40 are in contact with the heat sources 90 and transmit the heat to the heat pipe 20, the heat pipe 20 uniformly spreads the absorbed heat to the substrate 10 and dissipates the heat though the first fin group 30.

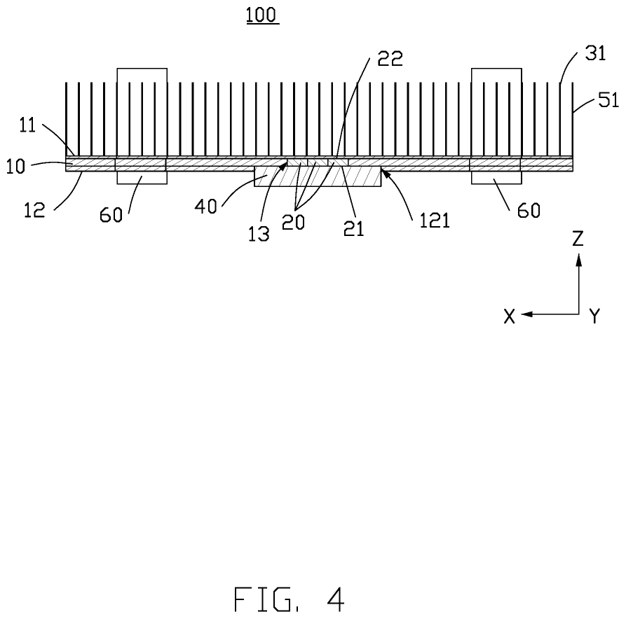

Referring to FIGS. 3 and 4, in at least one embodiment, a channel 13 for receiving the heat pipe 20 is defined in the substrate 10, a plurality of openings 121 are defined on the second surface 12, and each of the plurality of openings 121 communicates with the channel 13. Each of the plurality of heat conducting members 40 is embedded in the substrate 10 from one of the plurality of openings 121 and is in contact with the heat pipe 20. Each of the plurality of heat conducting members 40 is clamped with the substrate 10. A side of each of the plurality of heat conducting members 40 facing away from the heat pipe 20 protrudes from the second surface 12 to improve a stability of the contact between the plurality of heat conducting members 40 and the heat sources 90.

In at least one embodiment, a plurality of heat pipes 20 are arranged adjacently and received in the channel 13 to suit the heat transfer requirements. Optionally, the number of the heat pipes 20 may be two, three, four, and so on.

In at least one embodiment, a soldering layer or an adhesive layer may be arranged between a portion of each of the plurality of heat conducting members 40 in the substrate 10 and the substrate 10 to further improve a connection strength between the plurality of heat conducting members 40 and the substrate 10.

Referring to FIGS. 3 and 4, in at least one embodiment, the heat pipe 20 includes an evaporation surface 21 and a condensation surface 22. The evaporation surface 21 faces the second surface 12 and is in contact with the plurality of heat conducting members 40, the condensation surface 22 faces the first surface 11 and is in contact with the substrate 10. The heat pipe 20 has excellent temperature uniformity and thermal conductivity, so that the heat from the evaporation surface 21 can be quickly transferred to the condensation surface 22, thereby improving the heat transfer efficiency between the plurality of heat conducting members 40 and the substrate 10.

Specifically, a cooling medium (not shown) in the heat pipe 20. During use, the heat emitted by the heat sources 90 is transferred to the evaporation surface 21 through the plurality of heat conducting members 40, and the cooling medium on the evaporation surface 21 is heated and vaporized to absorb heat energy and rapidly expand in volume, so that the cooling medium in the gas phase quickly fills the entire heat pipe 20. When the cooling medium in the gas phase contacts the condensation surface 22, a condensation phenomenon occurs. The condensation phenomenon releases the heat on the condensation surface 22, and the condensation surface 22 transfers the heat to the substrate 10. The cooling medium condensed on the condensation surface 22 will return to the evaporation surface 21 for recirculation.

In at least one embodiment, the heat pipe 20 may be flat, and both the evaporation surface 21 and the condensation surface 22 are flat planes.

Referring to FIG. 3, in at least one embodiment, sides of the plurality of heat conducting members 40 contacting the heat pipe 20 are on a same horizontal plane, and the horizontal plane is parallel to the first surface 11, so that the heat pipe 20 is horizontal and the operation stability of the heat pipe 20 is improved. A thickness of each of the plurality of heat conducting members 40 from the heat pipe 20 to the corresponding heat source 90 is adaptively adjusted according to the heat sources 90 of different sizes. Specifically, the thickness of each of the plurality of heat conducting members 40 from the heat pipe 20 to the corresponding heat source 90 is inversely related to a length that the corresponding heat source 90 protrudes toward the second surface 12.

Referring to FIG. 1, in at least one embodiment, the first fin group 30 includes a plurality of first fins 31 arranged at intervals on the first surface 11 along a first direction X. Each of the plurality of first fins 31 extends along a second direction Y different from the first direction X. The second direction Y may be perpendicular to the first direction X. A first heat dissipation gap 30a is formed between any two adjacent first fins 31. When the airflow passes through the first heat dissipation gap 30a, the airflow exchanges heat with the first fins 31 to dissipate heat to the first fins 31.

In at least one embodiment, the heat sink 100 may further include a second fin group 50. The second fin group 50 is arranged on the first surface 11 and adjacent to the first fin group 30 along the second direction Y. The second fin group 50 includes a plurality of second fins 51 arranged at intervals on the first surface 11 along the first direction X. Each of the plurality of second fins 51 extends along the second direction Y. A second dissipation gap 50a is formed between any adjacent second fins 51.

The second fin group 50 and the first fin group 30 cooperate to dissipate heat from the substrate 10. Along the first direction X, each of the first fins 31 and each of the second fins 51 may be staggered. Further, along the first direction X, a width of the first dissipation gap 30a may be greater than a width of the second dissipation gap 50a, which reduces the risk of the first fin group 30 blocking airflow from entering the second fin group 50, thereby improving the air intake volume of the second fin group 50. So that the heat dissipation capability of the second fin group 50 and first fin group 30 to the substrate 10 is improved. In at least one embodiment, more than one second fins 51 may correspond to the first dissipation gap 30a.

The width of the first dissipation gap 30a is defined as L1, the width of the second dissipation gap 50a is defined as L2. In at least one embodiment, L1 is between 2.0 mm to 3.0 mm, that is, 2.0 mm≤L1≤3.0 mm; L2 is between 1.0 mm to 2.0 mm, that is, 1.0 mm≤L2≤2.0 mm.

In at least one embodiment, a ratio A between the width of the second dissipation gap 50a and the width of the first dissipation gap 30a satisfies the following conditions: A=L2/L1, ⅓≤A<1. In at least one embodiment, A=⅓.

Preferably, A may be ½, ⅔, and so on.

In at least one embedment, along the first direction X, a thickness of each of the plurality of first fins may be 0.3 mm, a thickness of each of the plurality of second fins may be 0.3 mm.

Referring to FIGS. 1 and 2, in at least one embodiment, at least one connecting hole 14 may be formed in an area of the substrate 10 without the heat pipe 20. Each of the at least one connecting hole 14 penetrates the substrate 10. The seat sink 100 may further include at least one fastener 60. Each of the at least one fastener 60 extends though one of the at least one connecting hole 14 to fix the substrate 10 to the electronic device with the plurality of heat sources 90.

In at least one embodiment, the number of the connecting holes 14 may be four and the connecting holes 14 are evenly distributed on the substrate 10, so that the fastening force between the substrate 10 and electronic device is evenly distributed.

In at least one embodiment, a heat conductivity coefficient of each of the plurality of heat conducting members 40 may be greater than a heat conductivity coefficient of the substrate 10, thereby improving the heat dissipation efficiency.

In at least one embodiment, each of the plurality of heat conducting members 40 may be made of copper, the substrate 10 may be made of aluminum. Compared with the traditional method in which the substrate made of copper is directly in contact with the heat sources, the amount of copper used can be reduced, and the production cost can be reduced.

In at least one embodiment, the first surface 11 and the second surface 12 are stacked along a third direction Z. Along the third direction Z, a thickness of the substrate 10 may be greater than or equal to 4 mm, a thickness of each of the plurality of heat conducting members 40 may be greater than or equal to 1 mm.

In at least one embodiment, the substrate 10, the first fin group 30 and the second fin group 50 may be integrally formed to improve the structure strength and reduce the production cost.

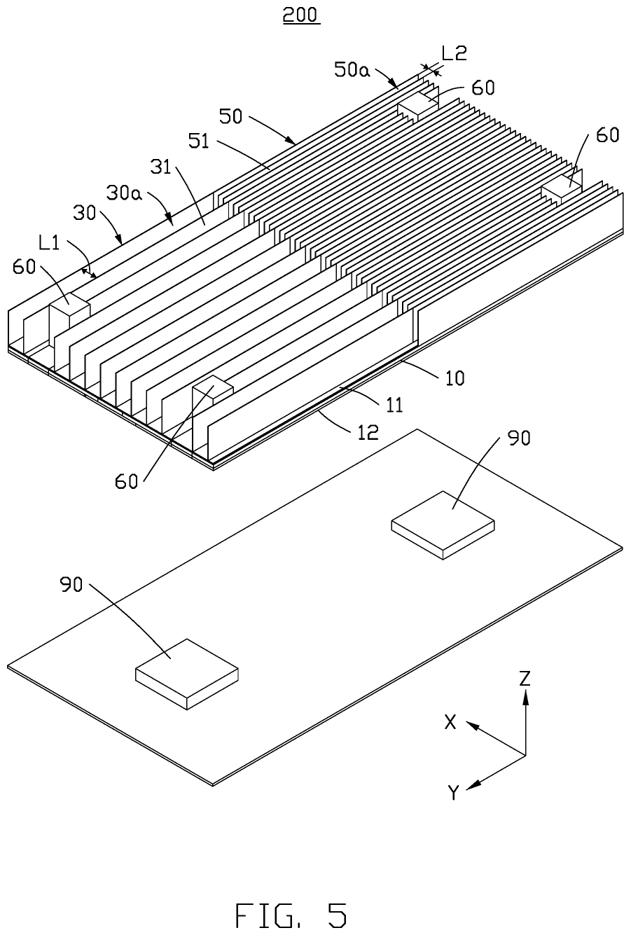

FIG. 5 illustrates an embodiment of an electronic device 200. The electronic device 200 includes a plurality heat sources 90 and the above heat sink 100. In at least one embodiment, the electronic device 200 may further include a circuit board 91, the plurality heat sources 90 are arranged on the circuit board 91.

In at least one embodiment, the plurality heat sources 90 are arranged on the circuit board 91 in a straight line, and correspondingly, the heat pipe 20 extends in a straight line.

In at least one embodiment, the plurality heat sources 90 are arranged on the circuit board 91 along an arc or irregularly, and correspondingly, the heat pipe 20 extends along an arc or irregularly.

In at least one embodiment, along the third direction X, a projection of a periphery of the substrate 10 on a plane where the circuit board 91 is located may be within the circuit board 91, which is beneficial to reduce the space occupied by the substrate 10 in the electronic device 200.

In at least one embodiment, along the third direction X, a projection of a periphery of each of the plurality of heat conducting members 40 on the a plane where the corresponding heat source 90 is located may overlap with a periphery of the corresponding heat source 90, thereby improving the heat dissipation efficiency.

In the above heat sink 100 and the electronic device 200, the plurality of heat conducting members 40 can be in contact with the plurality of heat sources at the same time to transfer the heat of the heat sources 90 to the heat pipe 20, and the heat is uniformly diffused to the substrate 10 through the heat pipe 20. Finally, the heat of the substrate 10 is dissipated through the first fin group 30. So that the heat dissipation efficiency to the heat sources is improved.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A heat sink comprising:
a substrate comprising a first surface and a second surface facing away from the first surface;
a heat pipe embedded in the substrate;
a first fin group on the first surface; and
a plurality of heat conducting members, wherein a part of each of the plurality of heat conducting members is embedded in the substrate from the second surface and contacts the heat pipe, the other part of each of the plurality of heat conducting members is located outside of the substrate.

2. The heat sink of claim 1, wherein a soldering layer or an adhesive layer is arranged between the part of each of the plurality of heat conducting members which is embedded in the substrate and the substrate.

3. The heat sink of claim 1, wherein the heat pipe comprises an evaporation surface and a condensation surface facing away from the evaporation surface, the evaporation surface contacts the plurality of heat conducting members, the condensation surface contacts the substrate.

4. The heat sink of claim 1, wherein the first fin group comprises a plurality of fins arranged at intervals on the first surface along a first direction, each of the plurality of fins extends along a second direction different from the first direction, a first heat dissipation gap is formed between any two adjacent first fins.

5. The heat sink of claim 4, wherein the heat sink further comprises a second fin group arranged on the first surface and adjacent to the first fin group along the second direction.

6. The heat sink of claim 5, wherein the second fin group comprises a plurality of second fins arranged at intervals on the first surface along the first direction, each of the plurality of second fins extends along the second direction different from the first direction, a second heat dissipation gap is formed between any two adjacent second fins.

7. The heat sink of claim 6, wherein along the first direction, each of the plurality of fins and each of the plurality of second fins are staggered.

8. The heat sink of claim 7, wherein a width of the first dissipation gap is greater than a width of the second dissipation gap.

9. The heat sink of claim 8, wherein more than one of the plurality of second fins correspond to the first dissipation gap.

10. The heat sink of claim 1, wherein a heat conductivity coefficient of each of the plurality of heat conducting members is greater than a heat conductivity coefficient of the substrate.

11. An electronic device comprising:
a plurality of heat sources; and
a heat sink comprising:
a substrate comprising a first surface and a second surface facing away from the first surface;
a heat pipe embedded in the substrate;
a first fin group on the first surface; and
a plurality of heat conducting members, wherein a part of each of the plurality of heat conducting members is embedded in the substrate from the second surface and contacts the heat pipe, the other part of each of the plurality of heat conducting members is located outside of the substrate;
wherein each of the plurality of heat conducting members contacts one of the plurality of heat sources.

12. The electronic device of claim 11, wherein a soldering layer or an adhesive layer is arranged between the part of each of the plurality of heat conducting members embedded in the substrate and the substrate.

13. The electronic device of claim 11, wherein the heat pipe comprises an evaporation surface and a condensation surface facing away from the evaporation surface, the evaporation surface contacts the plurality of heat conducting members, the condensation surface contacts the substrate.

14. The electronic device of claim 11, wherein the first fin group comprises a plurality of fins arranged at intervals on the first surface along a first direction, each of the plurality of fins extends along a second direction different from the first direction, a first heat dissipation gap is formed between any two adjacent first fins.

15. The electronic device of claim 14, wherein the heat sink further comprises a second fin group arranged on the first surface and adjacent to the first fin group along the second direction.

16. The electronic device of claim 15, wherein the second fin group comprises a plurality of second fins arranged at intervals on the first surface along the first direction, each of the plurality of second fins extends along the second direction different from the first direction, a second heat dissipation gap is formed between any two adjacent second fins.

17. The electronic device of claim 16, wherein along the first direction, each of the plurality of fins and each of the plurality of second fins are staggered.

18. The electronic device of claim 17, wherein a width of the first dissipation gap is greater than a width of the second dissipation gap.

19. The electronic device of claim 18, wherein more than one of the plurality of second fins correspond to the first dissipation gap.

20. The electronic device of claim 11, wherein a heat conductivity coefficient of each of the plurality of heat conducting members is greater than a heat conductivity coefficient of the substrate.
